(19) United States
(12) Patent Application Publication
(10) Pub. No.: US 2014/0175580 A1
(43) Pub. Date: Jun. 26, 2014

(54) MAGNETORESISTIVE MEMORY DEVICE AND FABRICTAION METHOD

(71) Applicant: Semiconductor Manufacturing International (Shanghai) Corporation, Shanghai (CN)

(72) Inventors: WENFU CHEN, Shanghai (CN); PAUL HE, Shanghai (CN); ALFRED ZHANG, Shanghai (CN); SEN SHI, Shanghai (CN)

(73) Assignee: Semiconductor Manufacturing International (Shanghai) Corporation, Shanghai (CN)

(21) Appl. No.: 14/056,046

(22) Filed: Oct. 17, 2013

(30) Foreign Application Priority Data
Dec. 20, 2012 (CN) 201210559867.1

(51) Int. Cl. H01L 43/12; H01L 43/02

(52) U.S. Cl. CPC H01L 43/12; H01L 43/02
USPC 257/421; 438/3

(57) ABSTRACT

A magnetoresistive memory device and a fabrication method are provided. A first dielectric layer disposed on a semiconductor substrate can include a groove formed therein. A cobalt metal layer can be formed over a bottom surface and a sidewall surface of the groove. A first metal layer can be formed over the cobalt metal layer. The first metal layer can fill the groove and be used as a first programming line of the magnetoresistive memory device. A second dielectric layer can be formed over the first dielectric layer and over the first metal layer. A magnetic tunnel junction can be formed over the second dielectric layer. The magnetic tunnel junction can be positioned corresponding to a position of the first metal layer. The magnetic tunnel junction can include an insulating layer sandwiched between a lower magnetic material layer and an upper magnetic material layer.

### CROSS-REFERENCES TO RELATED APPLICATIONS

This application claims priority to Chinese Patent Application No. CN201210559867.1, filed on Dec. 20, 2012, the entire contents of which are incorporated herein by reference.

### FIELD OF THE DISCLOSURE

The present disclosure relates to the field of semiconductor technology and, more particularly, relates to a magnetoresistive memory device and fabrication method.

### BACKGROUND

Magnetoresistive memory (e.g., magnetoresistive random access memory, MRAM) is a non-volatile memory (NVM) characterized with high integration density, high responding speed and write endurance. The magnetoresistive memory may become a mainstream product among storage devices with the advancement of processes, compared with a flash memory. The feature size of a flash memory cannot be infinitely reduced.

A main component of a magnetoresistive memory device is a magnetic tunnel junction (MTJ). The most simplified magnetic tunnel junction consists of a three-layer structure. Referring to FIG. 1, the magnetic tunnel junction includes: an insulating layer 12 sandwiched by an upper magnetic material layer 11 (a free ferromagnetic layer), and a lower magnetic material layer 13 (a fixed ferromagnetic layer).

When the magnetization direction of the upper magnetic material layer 11 is the same as the magnetization direction of the lower magnetic material layer 13, the resistance of the magnetic tunnel junction is the minimum. When the magnetization direction of the upper magnetic material layer 11 is 180 degrees from the magnetization direction of the lower magnetic material layer 13, the resistance of the magnetic tunnel junction is the maximum.

The storage can be defined as “0”, when the magnetization direction of the upper magnetic material layer 11 is the same as the magnetization direction of the lower magnetic material layer 13. And the storage can be defined as “1”, when the magnetization direction of the upper magnetic material layer 11 is 180 degrees from the magnetization direction of the lower magnetic material layer 13. Alternatively, definitions may be the opposite for storing information with the magnetic tunnel junction.

Methods for writing to the magnetic tunnel junction include magnetic field induced writing. The structure of a corresponding MRAM device is shown in FIG. 1. A typical magnetic tunnel junction usually includes an upper electrode 5 and a lower electrode 6. The upper electrode 5 is located above the upper magnetic material layer 11. The lower electrode 6 is located below the lower magnetic material layer 13. A first programming line 4 is positioned beneath the lower electrode 6. A second programming line 3 is positioned above the upper electrode 5. The second programming line 3 is vertical to the first programming line 4. The second programming line 3 is separated from the upper electrode 5 by an insulating layer (not shown) with no electrical connection. The first programming line 4 is separated from the lower electrode 6 by an insulating layer (not shown) with no electrical connection. The coercivity of the upper magnetic material layer 11 is lower than the coercivity of the lower magnetic material layer 13.

The process of magnetic field induced writing is as follows. When the control transistor 2 is at off state, selected voltages are applied to the second programming line 3 and the first programming line 4 for currents (also known as the drive currents) to pass through. When the currents pass through, magnetic fields are generated. As a result, in the magnetic tunnel junction located at the crossing point between the second programming line 3 and the first programming line 4, the upper magnetic material layer 11 is exposed to the strongest magnetic field such that the magnetization direction of the upper magnetic material layer 11 is changed. Because the coercivity of the lower magnetic material layer 13 is greater than the coercivity of the upper magnetic material layer 11, the magnetization direction of the lower magnetic material layer 13 is fixed and unchanged. When directions of the writing currents are simultaneously reversed, the direction of the strongest magnetic field is also reversed, to which the upper magnetic material layer 11 is exposed. Thus, digits of “0” and “1” can be written to the magnetic tunnel junction through “different directions of the magnetic field”.

However, when programming existing magnetoresistive memory devices, the first programming line often requires a high drive current. This adversely affects stability of the devices and increasing degree of device integration.

### BRIEF SUMMARY OF THE DISCLOSURE

One aspect of present disclosure includes a method for forming a magnetoresistive memory device. A first dielectric layer can be provided on a semiconductor substrate. A groove can be formed in the first dielectric layer. A cobalt metal layer can be formed over a bottom surface and a sidewall surface of the groove. A first metal layer can be formed over the cobalt metal layer. The first metal layer can fill the groove and be used as a first programming line of the magnetoresistive memory device. A second dielectric layer can be formed over the first dielectric layer and over the first metal layer. A magnetic tunnel junction can be formed over the second dielectric layer. The magnetic tunnel junction can be positioned corresponding to a position of the first metal layer. The magnetic tunnel junction can include an insulating layer sandwiched between a lower magnetic material layer and an upper magnetic material layer.

Another aspect of present disclosure includes a magnetoresistive memory device. A first dielectric layer can be disposed on a semiconductor substrate and include a groove disposed there-in. A cobalt metal layer can be disposed over a bottom surface and a sidewall surface of the groove. A first metal layer can be disposed over the cobalt metal layer to fill the groove. The first metal layer can be used as a first programming line of the magnetoresistive memory device. A second dielectric layer can be disposed over the first metal layer and over the first dielectric layer. A magnetic tunnel junction can be disposed over the second dielectric layer and positioned corresponding to a position of the first metal layer. The magnetic tunnel junction can include an insulating layer sandwiched between a lower magnetic material layer and an upper magnetic material layer.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-2 depict a conventional magnetoresistive memory device; and

FIGS. 3-11 depict cross-sectional views of an exemplary magnetoresistive memory device at various stages during its formation in accordance with various disclosed embodiments.

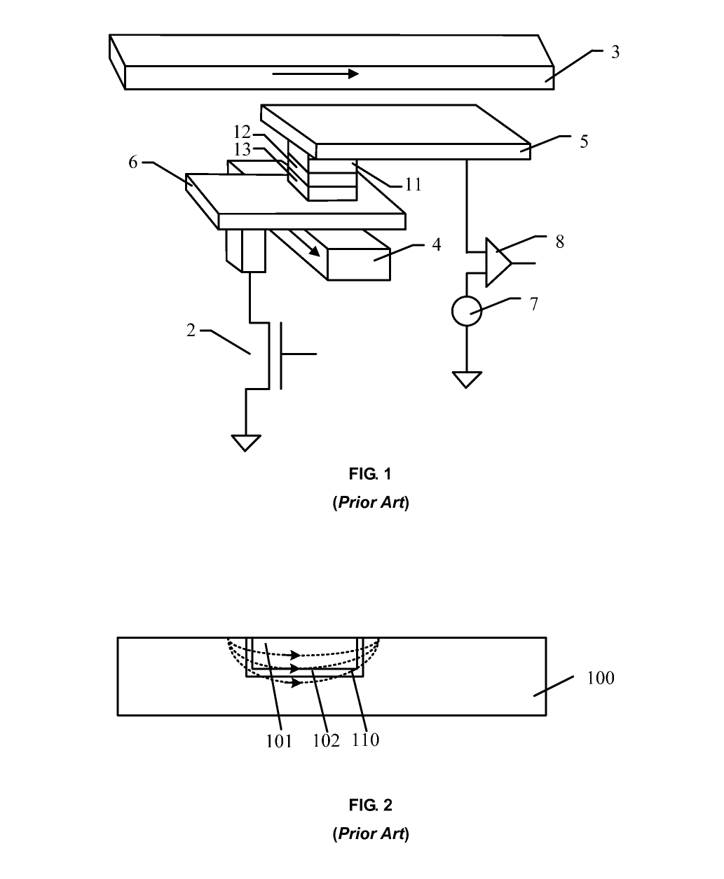

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts. For illustration purposes, the schematic drawings may be not to scale. The schematic drawings are solely illustrative, and should not limit the scope of the present disclosure. In addition, three-dimensional scales of length, width and depth should be included in practical fabrication process.

During programming of existing magnetoresistive memory devices, the first programming line often requires a high drive current. FIG. 2 depicts a cross-sectional view of a first programming line of a conventional magnetoresistive memory device. The first programming line includes: a substrate 100, a metal layer 101 located in the substrate 100, and a barrier layer 102 located between the metal layer 101 and the substrate 100. The metal layer 101 and the barrier layer 102 form the first programming line. The material of the metal layer 101 is usually copper. The material of the barrier layer 102 is usually Ta or TaN.

When programming the magnetoresistive memory devices, the magnetic field lines are scattered when the magnetic field lines 110 generated by the first programming line are transported through the metal layer 101 and the barrier layer 102 because copper, Ta, and TaN are not good conductors of magnetism (not sufficiently magnetically-conductive). The scattering of the magnetic field lines 110 weakens the influence of the magnetic field generated by the first programming line on the magnetic tunnel junction. This adversely affects programming of the magnetoresistive memory devices. In existing technology, in order to alleviate this phenomenon, the drive current needs to be increased. But increasing the drive current adversely affects the stability of the device and the increase in the degree of device integration.

In various embodiments, magnetically conductive metals can be coated on the programming lines to lower the drive current. Cobalt (Co) is a magnetically conductive metal, although cobalt deposition tool has limited hole-filling capability. In some cases, Co cannot be deposited at the bottom of interconnect metal trench or via. In addition, in existing technology, there is no CMOS (Complementary Metal-Oxide-Semiconductor) compatible process to manufacture a cladding with cobalt.

Various embodiments of the present disclosure provide a magnetoresistive memory device and its fabrication method. The fabrication method can include a CMOS compatible process. The magnetoresistive memory device includes a first dielectric layer having a groove formed within the first dielectric layer; a first metal layer, a cobalt metal layer, a magnetic tunnel junction, and/or a second dielectric layer. The first metal layer can fill the groove and serves as a first programming line of a magnetic tunnel junction. The cobalt metal layer can be formed between the first metal layer and the groove. The magnetic tunnel junction can be formed above the first metal layer. The second dielectric layer can be formed between the magnetic tunnel junction and the cobalt metal layer.

During programming of the magnetoresistive memory device, a drive current is applied to the first programming line. Because the cobalt metal layer has desired magnetic permeability, the cobalt metal layer outside of the first programming line can form a pathway for magnetic field lines. The magnetic field lines generated by the first programming line can be transported through the cobalt metal layer. As a result, the magnetic field lines can be effectively concentrated, which can enhance influence of the magnetic field generated by the first programming line on the magnetic tunnel junction. Compared with existing technology, a low drive current can be applied to the magnetoresistive memory device provided by the disclosed embodiments for programming the magnetoresistive memory device.

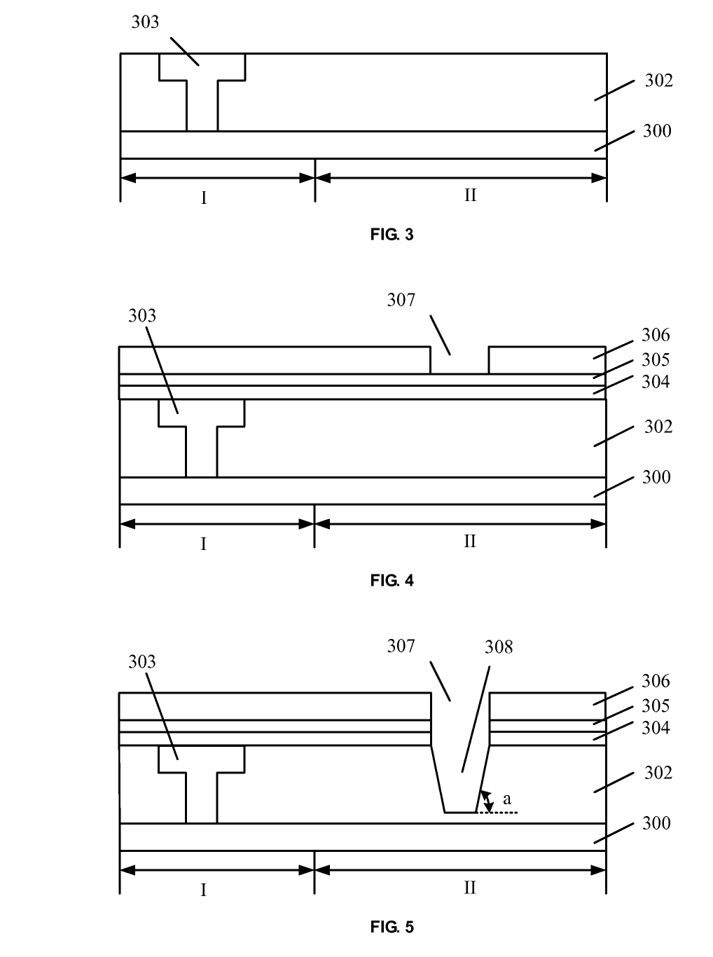

FIGS. 3-11 depict cross-sectional views of an exemplary magnetoresistive memory device at various stages during its formation in accordance with various disclosed embodiments.

Referring to FIG. 3, a semiconductor substrate 300 is provided. The semiconductor substrate 300 has a first region I and a second region II. The second region II is adjacent to the first region I. A first dielectric layer 302 is formed on the semiconductor substrate 300.

The semiconductor substrate 300 can be single crystal silicon (Si), single crystal germanium (Ge), silicon germanium (GeSi), and/or silicon carbide (SiC). The semiconductor substrate 300 can also be silicon-on-insulator (SOI), germanium-on-insulator (GOI), Group III-V compounds such as GaAs, and/or other suitable materials.

Semiconductor devices (not shown) can be formed on/in the semiconductor substrate. The semiconductor devices can be transistors, inductors, capacitors, etc.

The first dielectric layer 302 can be silicon oxide, silicon nitride, low-K dielectric material, and/or ultra-low-K dielectric material. An interconnect structure 303 can be formed within the first dielectric layer 302 in the first region I. The interconnect structure 303 can be electrically connected to the semiconductor devices (not shown) formed on/in the semiconductor substrate. The interconnect structure 303 can include a dual damascene structure. A first metal layer of the magnetoresistive memory device can subsequently be formed in the first dielectric layer 302 in the second region II.

The first dielectric layer 302 can include a single-layer structure or a multi-layer stacking structure. Although a single layer structure is shown in FIG. 3 for illustration purposes, the number of layers for the first dielectric layer 302 should not limit the scope of the present disclosure.

Referring to FIG. 4, an etch stop layer 304 is formed on the first dielectric layer 302. An anti-reflection layer 305 is formed on the etch stop layer 304. A mask layer 306 is formed on the anti-reflection layer 305. The mask layer 306 has an opening that exposes the anti-reflective layer 305 in the second region II. The position of the opening 307 corresponds to the position of a groove that is subsequently formed in the first dielectric layer 302 in the second region II.

The etch stop layer 304 can serve as a hard mask for the subsequent etching of the first dielectric layer, and also as a stop layer for the subsequent chemical mechanical polishing. The material of the etch stop layer 304 can be silicon nitride. The thickness of the etch stop layer 304 can range from about 400 angstroms to about 600 angstroms.

The anti-reflective layer 305 can be used to improve the precision of the photolithographic process. The anti-reflective layer 305 can include a single-layer structure of a bottom anti-reflective coating, or a double-layer stacking structure of a silicon oxynitride layer and a bottom anti-reflective coating. The material of the mask layer 306 can be photoresist or any suitable hard mask material.

Referring to FIG. 5, the anti-reflective layer 305 and the etch stop layer 304 are etched along the opening 307 using the mask layer 306 as an etch mask. Thus, a second opening can be formed in the anti-reflective layer 305 and the etch stop layer 304. The position of the second opening can correspond to the position of the opening 307. The first dielectric layer 302 is then etched, using the mask layer 306 and the etch stop layer 304 as mask, to form a groove 308 in the first dielectric layer 302.

The width of the groove 308 can be gradually reduced from the surface of the first dielectric layer 302 to the bottom of the groove 308 in the first dielectric layer 302. When a diffusion barrier layer and a cobalt metal layer are subsequently deposited, formation of protrusions can be prevented at the opening of the groove 308. That can prevent the opening of the groove 308 from being clogged by protrusions. The clogging can be adversely affect deposition of a first metal layer.

The sidewall of the groove 308 can have an inclined flat surface or an inclined curved surface. The extended line of the sidewall of the groove 308 can form an angle a with the surface of the semiconductor substrate 300. The angle a can range from about 80 degrees to about 85 degrees as shown in FIG. 5. When a diffusion barrier layer and a cobalt metal layer are subsequently formed, the protrusions formed at the opening of the groove 308 can reach minimum. The etching process to form the groove can be better controlled.

The process for forming the groove 308 can include a plasma etch process using an etching gas selected from CF₄, CHF₃, C₂F₆, CO, CHF, N₂, C₂F₆, CO, or a combination thereof.

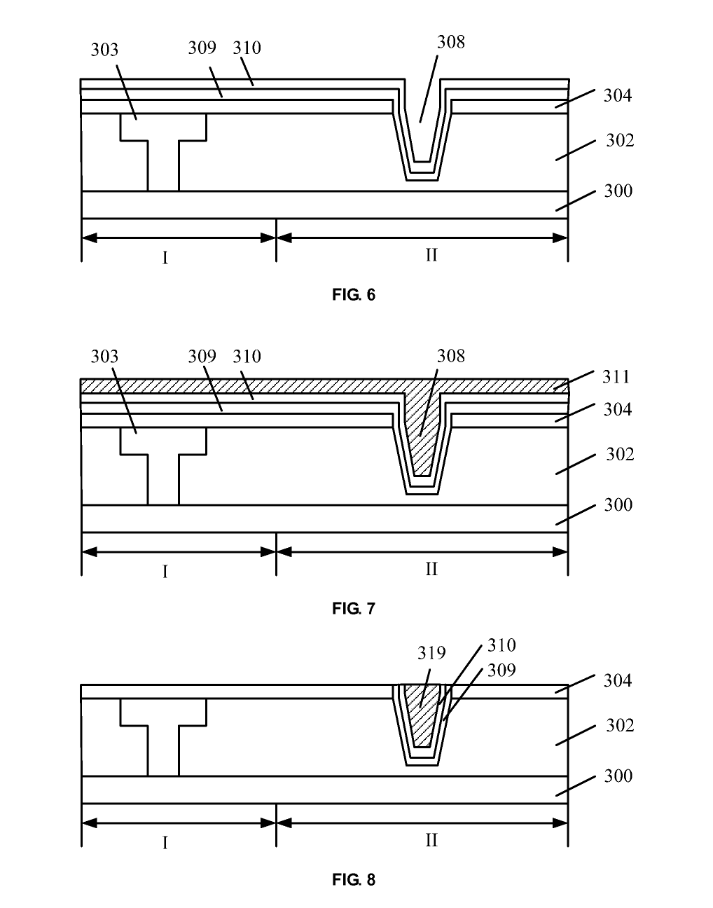

Referring to FIG. 6, the mask layer 306 and the anti-reflection layer 305 are removed. A cobalt metal layer 309 is formed on the bottom and sidewall surface of the groove 308 and on the etch stop layer 304. A second diffusion barrier layer 310 is formed on the cobalt metal layer 309.

Prior to forming the cobalt metal layer 309, a rounding treatment can be applied to the opening of the groove 308, so that the surface of the opening of the groove 308 can be rounded. Thus, the opening of the groove 308 can be enlarged. In addition, when the cobalt metal layer 309 and the second diffusion barrier layer 310 are formed, protrusion formation at the opening of the groove 308 can be prevented. Protrusion formation can block the opening of the groove 308, which can affect subsequent deposition of a first metal layer. The process used in the rounding treatment can be sputtering. The gas used in the sputtering can be argon gas.

The cobalt metal layer 309 is formed on the bottom and sidewall surface of the groove 308, and can serve as the cladding layer for a first metal layer that subsequently fills the groove 308. The first metal layer can be a first programming line of the magnetoresistive memory device. When drive current is applied to the first programming line, due to desirably good magnetic permeability of the cobalt metal layer 309, the cobalt metal layer 309 can form a pathway for the magnetic field lines. The magnetic field lines can be generated by the first programming line. The majority of such magnetic field lines can be transported through the pathway formed by the cobalt metal layer 309, and the magnetic field lines are not transported in the first dielectric layer 302 located outside of the cobalt metal layer 309. Thus, the magnetic field lines can be effectively focused, which can enhance the influence of the magnetic field (generated by the first programming line) on the magnetic tunnel junction. Therefore, the magnetoresistance memory device presently disclosed can be programmed with a lower drive current than existing technology.

The process of forming the cobalt metal layer 309 can include sputtering. The thickness of the cobalt metal layer 309 can range from about 100 angstroms to about 300 angstroms. The formed cobalt metal layer 309 can be uniform. In various embodiments, the thickness of the cobalt metal layer 309 refers to the thickness of the cobalt metal layer 309 on the sidewall of the groove 308.

After the cobalt metal layer 309 is formed, the second diffusion barrier layer 310 can be formed on the surface of the cobalt metal layer 309. The second diffusion barrier layer 310 can serve as a barrier layer for the metal in the first metal layer that is subsequently formed in the groove 308. The second diffusion barrier layer 310 can prevent the metal in the first metal layer from diffusing into the first dielectric layer 302. The second diffusion barrier layer 310 can also serve as an isolation layer between the cobalt metal layer 309 and the subsequently formed first metal layer, in order to prevent the cobalt metal and the metal in the first metal layer from a direct contact and from a chemically reaction to form an alloy. Forming an alloy can cause loss or reduction of the magnetic permeability of the cobalt metal layer 309.

The material of the second diffusion barrier layer 310 can be Ti, Ta, TiN, TaN, or a combination thereof. The thickness of the second diffusion barrier layer 310 can range from about 50 to about 100 angstroms. The process of forming the second diffusion barrier layer 310 can include a sputtering process.

In other embodiments, after the groove 308 is formed in the first dielectric layer 302, a first diffusion barrier layer (not shown) can be formed on the sidewall and the bottom surface of the groove 308. The cobalt metal layer 309 can be formed on the first diffusion barrier layer. The second diffusion barrier layer 310 can then be formed on the cobalt metal layer 309. The first metal layer can be formed on the second diffusion barrier layer 310 to fill the groove 308.

The material of the first diffusion barrier layer can be Ti, Ta, TiN, TaN, or a combination thereof. The first diffusion barrier layer can serve as a barrier layer for the metal in the cobalt metal layer 309, and can prevent the cobalt metal from diffusing into the first dielectric layer 302 and from affecting the isolation performance of the first dielectric layer 302. The process of forming the second diffusion barrier layer 310 can include a sputtering process.

Referring to FIG. 7, a first metal film 311 is formed on the surface of the second diffusion barrier layer 310 to fill the groove 308. The first metal film 311 can be used to form a first metal layer of the magnetoresistive memory device. The process of forming the first metal film 311 can be electroplating. Before the electroplating, a seed layer can be formed on the surface of the second diffusion barrier layer 310. The material of the first metal film 311 can be copper and/or tungsten.

Referring to FIG. 8, the first metal film 311, the seed layer (not shown), the second diffusion barrier layer 310, and the cobalt metal layer 309 are polished, e.g., by CMP (i.e., chemical mechanical polishing) using the etch stop layer 304 as a stop layer. The first metal film 311 remaining in the groove 308 is referred to as a first metal layer 319 as shown in FIG. 8. The first metal layer 319 can serve as the first programming line of the magnetoresistive memory device.

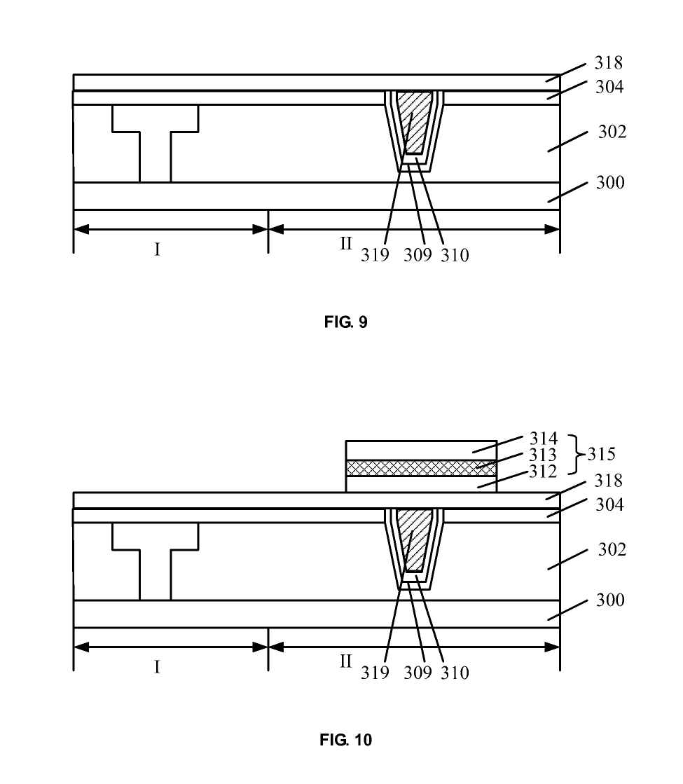

Referring to FIG. 9, a second dielectric layer 318 is formed on the etch stop layer 304 and on the first metal layer 319.

The second dielectric layer 318 can serve as an isolation layer between the first metal layer 319 and a magnetic tunnel junction to be subsequently formed. The material of the second dielectric layer 318 can be silicon oxide, silicon nitride, silicon oxynitride, silicon carboxide, etc.

Referring to FIG. 10, a magnetic tunnel junction 315 is formed on the second dielectric layer 318. The magnetic tunnel junction 315 can include a lower magnetic material layer 312, an insulating layer 313 located on the lower magnetic material layer 312, and an upper magnetic material layer 314 located on the insulating layer 313. The position of the magnetic tunnel junction 315 can correspond to the position of the first metal layer 319.

The lower magnetic material layer 312 and the upper magnetic material layer 314 can be a single-layer structure or a multi-layer stacking structure. In some embodiments, the lower magnetic material layer 312 can be a triple-layer stacking structure including a cobalt-iron alloy layer (CoFe), a ruthenium metal layer (Ru), and a cobalt-iron alloy layer (CoFe). The upper magnetic material layer 314 can be a triple-layer stacking structure including a boron-cobalt-iron alloy layer (CoFeB), a ruthenium metal layer (Ru), and a boron-cobalt-iron alloy layer (CoFeB). The material of the insulating layer 313 can be, e.g., magnesium oxide.

A lower electrode (not shown) can be formed between the lower magnetic material layer 312 and the second dielectric layer 318. An upper electrode (not shown) can be formed above the upper magnetic material layer. Any suitable process for forming the magnetic tunnel junction 315 can be encompassed herein.

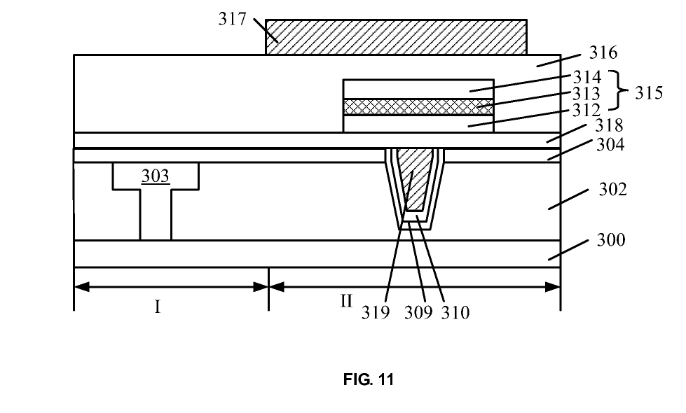

Referring to FIG. 11, a third dielectric layer 316 is formed on the second dielectric layer 318 and covers the magnetic tunnel junction 315. A second metal layer 317 is formed on the third dielectric layer 316. The second metal layer 317 can serve as a second programming line of the magnetoresistive memory device. The first programming line can form an angle with the second programming line. For example, the angle can be about 90 degrees or other suitable angles. The position of the second metal layer 317 can correspond to the position of the magnetic tunnel junction 315.

As disclosed, the magnetoresistive memory device formed by the disclosed method includes a semiconductor substrate 300, a first dielectric layer 302, an interconnect structure 303, a groove 308, a cobalt metal layer 309, a second diffusion barrier layer 310, a first metal layer 319, a second dielectric layer 318, a magnetic tunnel junction 315, a third dielectric layer 316, and/or a second metal layer 317.

The semiconductor substrate 300 has a first region I and a second region II. The first dielectric layer 302 is disposed on the semiconductor substrate 300. The interconnect structure 303 is disposed within the first dielectric layer 302 in the first region I. The groove 308 is formed in the first dielectric layer 302 in the second region II. The cobalt metal layer 309 is disposed on the bottom and sidewall surface of the groove 308. The second diffusion barrier layer 310 is disposed on the cobalt metal layer 309. The first metal layer 319 is disposed on the second diffusion barrier metal layer 310 and fills the groove 308. The first metal layer 319 can serve as a first programming line of the magnetoresistive memory device.

The second dielectric layer 318 is disposed on the first metal layer 319 and over the first dielectric layer 302. The magnetic tunnel junction 315 is disposed on the second dielectric layer 318. The magnetic tunnel junction 315 includes a lower magnetic material layer 312, an insulating layer 313 located on the lower magnetic material layer 312, and an upper magnetic material layer 314 located on the insulating layer 313. The third dielectric layer 316 is disposed on the second dielectric layer 318. The third dielectric layer 316 covers the magnetic tunnel junction 315. The second metal layer 317 is disposed on the third dielectric layer 316. The second metal layer 317 can serve as a second programming line of the magnetoresistive memory device. The first programming line, e.g., the first metal layer 319, can make an angle with the second programming line, e.g., the second metal layer 317, and the angle can be about 90 degrees or any other suitable angles.

In accordance with various disclosed embodiments, the method of forming a magnetoresistive memory device is provided. After a groove is formed in a first dielectric layer, a cobalt metal layer is formed on the bottom and sidewall surface of the groove. A first metal layer is then formed on the cobalt metal layer and fills the groove. The first metal layer can serve as a first programming line of the magnetoresistive memory device. When a magnetic tunnel junction of the magnetoresistance memory device is subsequently formed, the forming process can be simple. In addition, because the cobalt metal layer has desirably good magnetic permeability, the cobalt metal layer that is formed outside of the first programming line can form a pathway for magnetic field lines. The magnetic field lines generated by the first programming line can be transported through the cobalt metal layer and be effectively focused.

Further, the width of the groove can be gradually reduced from the surface of the first dielectric layer to the bottom of the groove. When a diffusion barrier layer and a cobalt metal layer are subsequently deposited, formation of protrusions can be prevented at the opening of the groove. That can prevent the opening of the groove from being clogged by protrusions. The clogging can adversely affect deposition of the first metal layer.

The sidewall of the groove can include an inclined flat surface or an inclined curved surface. The sidewall of the groove can form an angle with a direction of the surface of the semiconductor substrate. The angle can range from about 80 degrees to about 85 degrees. When the diffusion barrier layer and the cobalt metal layer are subsequently formed, the protrusions formed at the opening of the groove can be minimized. The etching process to form the groove can be better controlled.

Further, after the cobalt metal layer is formed, a second diffusion barrier layer can be formed on the surface of the cobalt metal layer. The second diffusion barrier layer can serve as a barrier layer for the metal in the first metal layer that is subsequently formed in the groove to prevent metal in the first metal layer from diffusing into the first dielectric layer. The second diffusion barrier layer can also serve as an isolation layer between the cobalt metal layer and the subsequently formed first metal layer, in order to prevent the cobalt metal and the metal in the first metal layer from direct contacts and from chemical reactions to form an alloy. Forming an alloy can cause loss or reduction of the magnetic permeability of the cobalt metal layer.

Further, after the groove is formed in the first dielectric layer, a first diffusion barrier layer can be formed on the sidewall and the bottom surface of the groove. The cobalt metal layer can be formed on the first diffusion barrier layer. The second diffusion barrier layer can then be formed on the cobalt metal layer. The first metal layer can be formed on the second diffusion barrier layer and fill the groove. The first diffusion barrier layer can serve as a barrier layer for the cobalt metal layer, and can prevent the cobalt metal from diffusing into the first dielectric layer and affecting the isolation performance of the first dielectric layer.

In this manner, a magnetoresistive memory device includes: a groove in a first dielectric layer; a first metal layer filling in the groove used as a first programming line of the magnetoresistive memory device; a cobalt metal layer formed between the first metal layer and the groove; a magnetic tunnel junction located above the first metal layer, and/or a second dielectric layer formed between the magnetic tunnel junction and the cobalt metal layer.

When programming the magnetoresistive memory device, a drive current is applied to the first programming line and the cobalt metal layer disposed outside the first programming line can form a pathway for the magnetic field lines due to the desirably good magnetic permeability of the cobalt metal layer. The magnetic field lines generated by the first programming line can be transported through the cobalt metal layer. Thus, the magnetic field lines can be effectively focused to enhance the influence of the magnetic field (generated by the first programming line) on the magnetic tunnel junction. Therefore, the disclosed magnetoresistance memory device can be programmed with a lower drive current than existing technology.

In various embodiments, the cobalt metal layer can also serve as a Cu diffusion barrier layer when the first metal layer includes Cu. The cobalt metal layer can prevent metal in the first metal layer from diffusing into the first dielectric layer and affecting the isolation performance of the first dielectric layer.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A method for forming a magnetoresistive memory device, comprising:
providing a first dielectric layer on a semiconductor substrate;
forming a groove in the first dielectric layer;
forming a cobalt metal layer over a bottom surface and a sidewall surface of the groove;
forming a first metal layer over the cobalt metal layer, wherein the first metal layer fills the groove and is used as a first programming line of the magnetoresistive memory device;
forming a second dielectric layer over the first dielectric layer and over the first metal layer; and
forming a magnetic tunnel junction over the second dielectric layer, wherein the magnetic tunnel junction is positioned corresponding to a position of the first metal layer, and wherein the magnetic tunnel junction includes an insulating layer sandwiched between a lower magnetic material layer and an upper magnetic material layer.

2. The method of claim 1, wherein a width of the groove is gradually reduced from a top surface of the first dielectric layer to the bottom surface of the groove to prevent formation of protrusions at an opening of the groove when forming a cobalt metal layer.

3. The method of claim 1, wherein the sidewall surface of the groove forms an angle with a direction of the top surface of the first dielectric layer, and the angle ranges from about 80 degrees to about 85 degrees.

4. The method of claim 1, wherein the groove is formed by a plasma etch using an etch gas including CF₄, CH F₃, C₂F₆, CO, CHF, N₂, C₂F₆, CO, or a combination thereof.

5. The method of claim 1, further including applying a rounding treatment to an opening of the groove.

6. The method of claim 5, wherein the rounding treatment includes a sputtering process.

7. The method of claim 6, wherein the sputtering process uses an argon gas.

8. The method of claim 1, wherein the cobalt metal layer is formed by a sputtering process, and the cobalt metal layer has a thickness ranging from about 100 angstroms to about 300 angstroms.

9. The method of claim 1, further including:
forming a second diffusion barrier layer between the cobalt metal layer and the first metal layer.

10. The method of claim 1, further including:
forming a first diffusion barrier layer over the sidewall surface and the bottom surface of the groove prior to forming the cobalt metal layer; and
forming a second diffusion barrier layer on the cobalt metal layer, wherein the first metal layer is formed on the second diffusion barrier layer to fill the groove.

11. The method of claim 10, wherein the first diffusion barrier layer or the second diffusion barrier is made of a material including Ti, Ta, TiN, TaN, or a combination thereof, and wherein the first diffusion barrier layer or the second diffusion barrier layer has a thickness ranging from about 50 angstroms to about 100 angstroms.

12. The method of claim 1, further including forming an etch stop layer on the first dielectric layer.

13. The method of claim 1, further including:
forming a third dielectric layer on the second dielectric layer, wherein the third dielectric layer covers the magnetic tunnel junction; and
forming a second metal layer on the third dielectric layer, wherein the second metal layer is used as a second programming line of the magnetoresistive memory device, and the second metal layer is positioned corresponding to a position of the magnetic tunnel junction.

14. A magnetoresistive memory device, comprising:
a first dielectric layer disposed on a semiconductor substrate, wherein the first dielectric layer includes a groove disposed there-in;
a cobalt metal layer disposed over a bottom surface and a sidewall surface of the groove;
a first metal layer disposed over the cobalt metal layer, wherein the first metal layer fills the groove and is used as a first programming line of the magnetoresistive memory device;
a second dielectric layer disposed over the first metal layer and over the first dielectric layer; and
a magnetic tunnel junction disposed over the second dielectric layer, wherein the magnetic tunnel junction is positioned corresponding to a position of the first metal layer, and wherein the magnetic tunnel junction includes an insulating layer sandwiched between a lower magnetic material layer and an upper magnetic material layer.

15. The device of claim 14, wherein a width of the groove is gradually reduced from a top surface of the first dielectric layer to the bottom surface of the groove and wherein the sidewall surface of the groove forms an angle with a direction of the top surface of the first dielectric layer ranging from about 80 degrees to about 85 degrees.

16. The device of claim 14, wherein the cobalt metal layer has a thickness ranging from about 100 angstroms to about 300 angstroms.

17. The device of claim 14, wherein a second diffusion barrier layer is disposed between the cobalt metal layer and the first metal layer.

18. The device of claim 14, wherein a first diffusion barrier layer is disposed between the cobalt metal layer and the groove, and wherein a second diffusion barrier layer is disposed between the cobalt metal layer and the first metal layer.

19. The device as in claim 18, wherein the first diffusion barrier layer or the second diffusion barrier is made of a material including Ti, Ta, TiN, TaN, or a combination thereof, and wherein the first diffusion barrier layer or the second diffusion barrier layer has a thickness ranging from about 50 angstroms to about 100 angstroms.

20. The device of claim 14, further including:
a third dielectric layer disposed on the second dielectric layer, wherein the third dielectric layer covers the magnetic tunnel junction; and
a second metal layer disposed on the third dielectric layer, wherein the second metal layer is used as a second programming line of the magnetoresistive memory device, and the second metal layer is positioned corresponding to a position of the magnetic tunnel junction.
